(19) United States
(12) Patent Application Publication
(10) Pub. No.: US 2005/0279637 A1
(43) Pub. Date: Dec. 22, 2005

(54) Methods of forming target/backing plate assemblies comprising ruthenium, methods of electrolytically processing ruthenium, and container-shaped physical vapor deposition targets comprising ruthenium

(76) Inventors: Michael R. Pinter, Spokane, WA (US); Janine K. Kardokus, Liberty Lake, WA (US)

Correspondence Address: WELLS ST. JOHN P.S., 601 W. FIRST AVENUE, SUITE 1300, SPOKANE, WA, 99201, US

(21) Appl. No.: 10/874,848

(22) Filed: Jun. 22, 2004

(51) Int. Cl. C23C 14/34

(52) U.S. Cl. 205/78; 205/264; 204/298.12; 204/298.13

(57) ABSTRACT

The invention includes a method of forming a target/backing plate assembly in which a backing plate construction is provided and a ruthenium-containing target is electrolytically deposited onto the backing plate construction. The backing plate construction can be in the form of a container shape having an interior region, and the ruthenium-containing target can be electrically deposited within the interior region of the container shape. The invention also includes target/backing plate constructions which have ruthenium-containing targets. The invention also includes a method of electrolytically processing ruthenium. A cathode is provided and an electrically conductive sacrificial material is provided over the cathode. A ruthenium-containing material is electrolytically deposited on the sacrificial material. The sacrificial material and the ruthenium-containing material are removed from the cathode, and then the ruthenium-containing material is separated from the sacrificial material.

### TECHNICAL FIELD

The invention pertains to methods of electrolytically processing ruthenium and to methods of forming target/backing plate assemblies in which the target comprises ruthenium. The invention also pertains to container-shaped physical vapor deposition targets having ruthenium-containing materials.

### BACKGROUND OF THE INVENTION

Ruthenium is an expensive material which can have application for utilization in semiconductor devices.

Among the methods which can be utilized for depositing ruthenium and ruthenium-containing materials during semiconductor device fabrication is physical vapor deposition. The physical vapor deposition sputter-deposits ruthenium and/or ruthenium-containing materials from a ruthenium-containing target.

A ruthenium-containing target is typically adhered within a physical vapor deposition apparatus as a target/backing plate assembly. Specifically, the target is bonded to a backing plate, and then the backing plate is utilized to retain the target/backing plate assembly within the physical vapor deposition apparatus. Utilization of a target/backing plate assembly allows the precious ruthenium to be limited to regions where sputtering from the target occurs, while using the backing plate material in regions where structural support to the physical vapor deposition apparatus is a primary function. Accordingly, the amount of ruthenium material in a target/backing plate construction can be reduced relative to the ruthenium material that would be utilized in a monolithic target construction (i.e., in a target construction in which the ruthenium is provided both in regions in where sputtering occurs, and in regions where a primary function is structural support to a physical vapor deposition apparatus).

Various methods have been proposed for purification of ruthenium, with an exemplary method being an electrolytic method described in U.S. Pat. No. 6,309,529. However, in light of the potential usefulness of ruthenium-containing materials and the high cost of utilizing such materials, there remains a need to develop additional processing methods for purification of ruthenium and for incorporation of ruthenium-containing target materials into target/backing plate constructions.

### SUMMARY OF THE INVENTION

In one aspect, the invention encompasses a method of forming a target/backing plate assembly. A backing plate construction is provided, and a ruthenium-containing target is electrolytically deposited onto the backing plate construction. The backing plate construction can be in a container shape. The container shape is defined to have a closed end and an open end, and to have a sidewall extending from the closed end to the open end. The container shape comprises an interior region which includes an interior surface of the closed end and an interior surface of the sidewall. The ruthenium-containing target is electrolytically deposited along at least a portion of the interior region of the container shape.

In one aspect, the invention encompasses a container-shaped physical vapor deposition target. The target includes a first conductive material in a container shape. The container shape includes an interior region, and the first conductive material includes an interior surface along the interior region. A ruthenium-containing material is along at least a portion of the interior surface of the first conductive material, and is of a different chemical composition than the first conductive material.

In one aspect, the invention encompasses a method of electrolytically processing ruthenium. A cathode is provided, and an electrically conductive sacrificial material is provided over the cathode. A ruthenium-containing material is electrolytically deposited on the sacrificial material. The sacrificial material and the ruthenium-containing material are removed from the cathode, and subsequently the ruthenium-containing material is separated from the sacrificial material.

### BRIEF DESCRIPTION OF THE DRAWINGS

Preferred embodiments of the invention are described below with reference to the following accompanying drawings.

FIG. 1 is a diagrammatic, cross-sectional side view of an exemplary target/backing plate construction of the present invention.

FIG. 2 is a diagrammatic, cross-sectional side view of another exemplary target/backing plate construction of the present invention.

FIG. 3 is a diagrammatic, cross-sectional side view of an electrolytic apparatus shown at an exemplary processing stage of an exemplary aspect of the present invention.

FIG. 4 is a flowchart diagram of an exemplary process of the present invention for purifying ruthenium-containing materials.

FIG. 5 is a diagrammatic, cross-sectional view of an electrolytic apparatus at a processing stage of the FIG. 4 process.

FIG. 6 is a view of the FIG. 5 apparatus shown at a processing stage subsequent to that of FIG. 5.

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

As investigations continue into the utilization of ruthenium in semiconductor fabrication processes, there is a continuing desire to develop improved target/backing plate constructions comprising ruthenium-containing targets. Commercially-available ruthenium is typically of lower purity than that desired for utilization in physical vapor deposition targets. For instance, commercially-available ruthenium will frequently have a purity of from about 99.9 weight percent to about 99.99 weight percent, and a typical desired purity of a ruthenium-containing target utilized in a physical vapor deposition process is 99.999 weight percent or higher. Additionally, fabrication of ruthenium-containing target materials can be difficult, in that the high cost of ruthenium can create a substantial desire to alleviate wastage of ruthenium starting materials, which in turn can create a substantial desire to reduce the number of processing steps and to eliminate processing steps which can be particularly wasteful of ruthenium-containing materials.

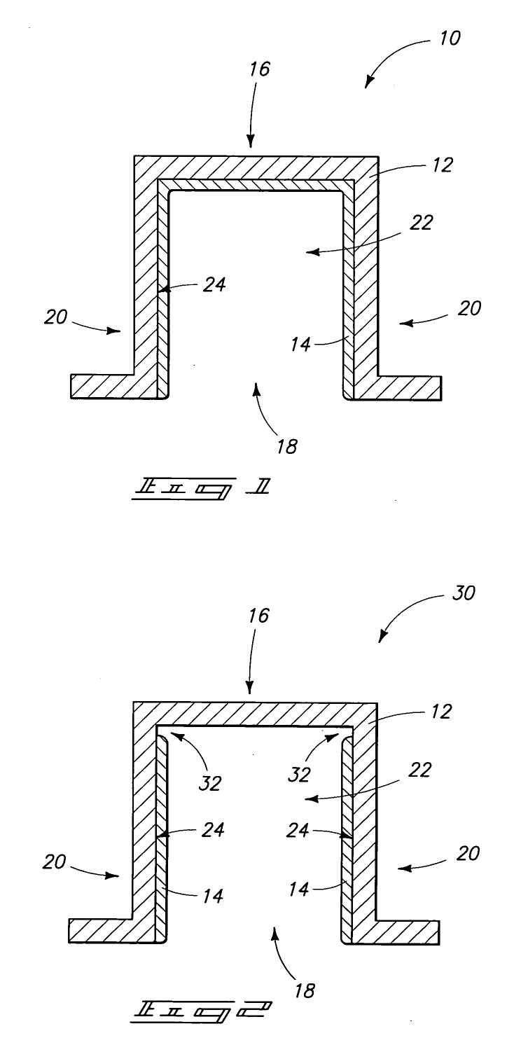

One aspect of the present invention is a recognition that it can be desired to incorporate ruthenium-containing target materials into container-shaped physical vapor deposition targets. For purposes interpreting this disclosure and the claims that follow, a container-shaped physical vapor deposition target is defined as a physical vapor deposition target having a closed-ended cavity extending therein, and in which a predominant feature of the target is the cavity. FIGS. 1 and 2 illustrate exemplary container-shaped physical vapor deposition target/backing plate assemblies of the present invention.

Referring initially to FIG. 1, such shows a target/backing plate assembly 10 comprising a backing plate 12 having a target 14 joined thereto. Backing plate 12 can comprise any suitable material, and typically will comprise metals and/or metal alloys so that the backing plate is electrically and thermally conductive. In particular aspects, backing plate 12 can comprise, consist essentially of, or consist of copper or aluminum. For instance, the backing plate can comprise 99.9 weight percent copper.

Target 14 is a ruthenium-containing material. In particular aspects, target 14 can comprise, consist essentially of, or consist of ruthenium. For instance, target 14 can comprise at least 99.9 weight percent ruthenium, at least 99.99 weight percent ruthenium, at least 99.995 weight percent ruthenium, at least 99.999 weight percent ruthenium, or higher purities of ruthenium.

The backing plate 12 of assembly 10 can be considered to be a first conductive material in a container shape. Such container shape includes a closed end 16, an open end 18, and sidewalls 20 extending from the closed end to the open end.

The target/backing plate assembly of FIG. 1 can have any suitable shape, and can correspond to a so-called hollow cathode magnetron (HCM) target. The assembly 10 would typically be circular when viewed from above or below. Accordingly the pair of sidewalls in the shown cross-sectional view of FIG. 1 would typically be parts of a single circular sidewall. Although a container-shaped target/backing plate structure is shown, it is to be understood that the invention can have application for any geometry of target/backing plate structure, and accordingly encompasses embodiments (not shown) which are not container-shaped structures.

The container shape of the backing plate 12 includes an interior region 22, and an interior surface 24 extending along the interior region. The interior surface 24 extends along an interior of the sidewalls 20 and along an interior of the closed end 16.

In the aspect of FIG. 1, ruthenium-containing material 14 has a substantially common uniform thickness across the interior surfaces of the sidewalls 20 and along the interior surface of the closed end 16. The thickness of material 14 can be about ¼″ in some applications, and in other applications can be thicker than ¼″ or thinner than ¼″.

FIG. 2 shows a target/backing plate assembly 30 illustrating another aspect of the invention. In referring to FIG. 2, similar numbering will be utilized as was used above in describing FIG. 1, where appropriate.

The construction of FIG. 2 comprises the backing plate 12 described previously with reference to FIG. 1. Such backing plate is in the above-described container shape having the closed end 16, open end 18, and sidewalls 20 extending from the closed end to the open end. The container-shaped backing plate also comprises the interior region 22, and the interior surface 24 extending along the interior region.

Construction 30 of FIG. 2 comprises the ruthenium-containing target material 14 discussed above. However, in contrast to the construction 10 of FIG. 1, the construction 30 of FIG. 2 has the ruthenium-containing target material 14 along only a portion of the interior surface 24. Specifically, the target material 14 is along the interior regions of sidewalls 20, but does not extend along the interior surface of closed-end 16.

The target material 14 is spaced from the interior surface of closed end 16 by gaps 32 in the shown aspect of the invention, and accordingly does not even contact the closed end 16. It is to be understood, however, that the invention encompasses other aspects (not shown) in which the target material 14 along the interior surfaces of the sidewalls extends to the interior surface of closed end 16 but does not extend across the closed end, and accordingly gaps 32 are omitted. Also, although the shown aspect of the invention has no target material formed along the interior surface of closed end 16, it is to be understood that the invention encompasses other aspects (not shown) in which the target material 14 is along the interior surface of both the closed end 16 and the sidewalls 20, but is thicker along the sidewalls 20 than along the closed end 16. Thus, it is to be understood that the aspect of FIG. 2 is an exemplary aspect of an embodiment of the invention in which target material 14 along the interior regions of sidewalls 20 of the shown container-shaped target is thicker than any target material along the predominant portion of the interior surface of the closed end 16 of the target, which includes aspects in which no target material is along the interior surface of the closed end 16, as well as aspects in which some target material is along the interior surface of closed end 16.

The embodiment of FIG. 2 can be advantageous relative to the embodiment of FIG. 1 in some aspects of the invention. Specifically, it is common for the sputtering from a container-shaped target to predominately, and frequently substantially entirely, occur from the interior sidewall surfaces of the target rather than from an interior of an upper closed end of the target/backing plate assembly. Accordingly, the embodiment of FIG. 2 advantageously does not provide the expensive ruthenium-containing material in regions of a target/backing plate assembly where minimal, if any, sputtering will occur during a sputter-deposition process.

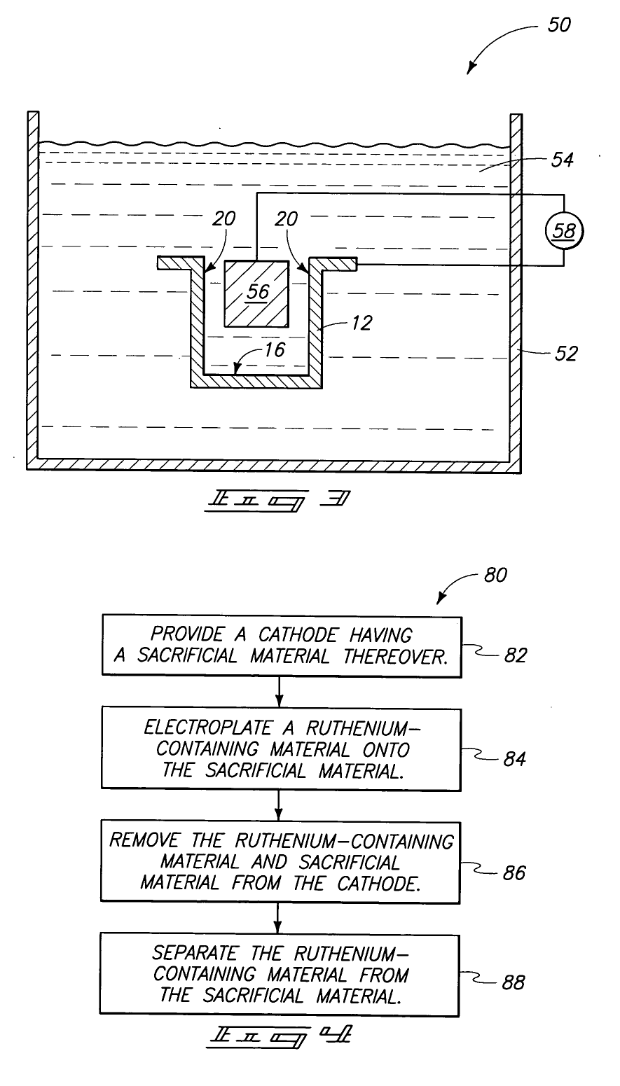

The target/backing plate assemblies 10 and 30 of FIGS. 1 and 2 can be formed by any suitable method. An exemplary method is an electrolytic process in which target material 14 is electrolytically deposited onto the interior surface 24 of the backing plate construction 12. Such aspect of the invention is described with reference to an electrolytic apparatus 50 in FIG. 3.

Apparatus 50 comprises a vessel 52 having an electrolytic bath 54 retained therein. A backing plate construction 12 is within the bath. Backing plate construction 12 is typically supported by appropriate support members (not shown). An anode 56 is also within the bath. Anode 56 can also be supported by appropriate support structures (not shown). Anode 56 is electrically connected with backing plate construction 12 through a power source 58. Backing plate 12 thus becomes a cathode during an electroplating process.

In operation, one or both of anode 56 and bath 54 comprises ruthenium, and electrical current is supplied from source 58 to transfer the ruthenium onto an interior surface of backing plate 12 to form the target constructions 14 described above with reference to FIGS. 1 and 2.

In an exemplary aspect of the invention, bath 54 is an aqueous solution containing dissolved ruthenium salts. For instance, the bath can contain a ruthenium halide salt (such as ruthenium chloride, and/or any other suitable ruthenium salt). If ruthenium chloride is utilized, such can be provided to a concentration within the solution of from greater than 0 grams per liter to about 10 grams per liter. An acid can be added to enhance solubility of ruthenium. For instance, sulfuric acid can be added to a concentration of from about 5 to 10% (by volume) to enhance the solubility of the ruthenium salt in the aqueous solution. The electroplating can be conducted utilizing a power of about 100 amps per square foot. The bath temperature during the electroplating can be maintained at any suitable temperature from about the freezing point of the bath to about the boiling point of the bath. If relatively high temperatures are utilized, such can increase a rate of electroplating but can result in rougher deposits of target material than if relatively low temperatures are utilized. It can be preferred that the bath temperature be about 160° F. The electroplating procedure can be any suitable procedure, including, for example, pulse plating or periodic reverse plating.

In some aspects of the invention, the anode 56 can comprise no ruthenium, so that all of the ruthenium transferred to form target material 14 (FIGS. 1 and 2) comes from salts dissolved in bath 54. In other aspects, at least some of the ruthenium transferred to form the target material can be initially provided as part of anode 56. For instance, the anode 56 can comprise ruthenium-containing particles retained within an electrically conductive screen.

The electroplating conditions described above are exemplary conditions, and any suitable conditions can be utilized. For instance, various conditions described in U.S. Pat. No. 6,309,529 can be utilized in some aspects of the invention.

The thickness of target material 14 on the interior sidewalls of the backing plate construction 12 relative to the thickness on the interior region of the closed end 16 can be manipulated by the relative size of anode 56 and the placement of anode 56 during electroplating of the target material onto the backing plate. Specifically, if a relatively small anode 56 is used (as shown) and is provided to be closer to the interior region of the sidewalls than to the interior region of the closed end 16, ruthenium-containing target material will tend to selectively deposit on the interior regions of the sidewalls rather than on the interior region of the closed end. In contrast, if a large anode is used which is approximately equally spaced from the interior region of closed end 16 and the interior regions of sidewalls 20, then ruthenium-containing target material will tend to deposit uniformly across the closed end 16 interior region as well as along the interior regions of the sidewalls 20. Accordingly, the above-discussed target/backing plate construction 10 can be formed by utilizing a relatively large anode which is equidistantly spaced from the closed end 16 and sidewalls 20 during electroplating of target material 14, whereas the target/backing plate construction 30 of FIG. 2 can be formed by utilizing a relatively small anode having surfaces which are closer to the sidewalls 20 than to the closed end 16 of the backing plate construction.

Although the ruthenium-containing material is described and shown as being deposited only along an interior surface of the container-shaped backing plate, it is to be understood that the invention includes other aspects (not shown) in which the ruthenium-containing material is also electrolytically deposited on the exterior surface of the container-shaped backing plate.

The electroplating of ruthenium target material directly onto a backing plate can provide numerous advantages. Such advantages can include bypassing of metal-working and bonding procedures commonly associate with target/backing plate assembly fabrication, which can enable relatively low cost and low waste formation of a properly-shaped target or near-net-shaped target in a target/backing plate construction.

FIGS. 1-3 describe one aspect of the invention. Another aspect of the invention is a recognition that it can be desired to utilize metallic electrodes for purification of ruthenium, and the further recognition that it can be difficult to remove ruthenium from traditional materials utilized for metallic electrodes, such as, for example, titanium plates. Specifically, it can be difficult to remove ruthenium from electrodes comprising, consisting essentially of, or consisting of titanium. Accordingly, it is desired to develop a processing method whereby a titanium-containing plate (or another metallic plate) can be utilized as a cathode during purification of ruthenium, and whereby the ruthenium can be readily removed from the cathode. In one aspect of the invention, such is accomplished by providing an electrically-conductive sacrificial material over the titanium-comprising cathode, and then electroplating ruthenium onto the sacrificial material. The sacrificial material is preferably something which is relatively easy to remove from the cathode material. For instance, if the cathode comprises, consists essentially of, or consists of titanium, the sacrificial material can comprise, consist essentially of, or consist of copper. The ruthenium electroplated onto the copper is highly purified by the electroplating process, and can, for example, be 99.9 weight percent ruthenium, 99.99 weight percent ruthenium, 99.995 weight percent ruthenium, or even 99.999 weight percent ruthenium or higher purity. The sacrificial material containing the highly purified ruthenium thereon is stripped from the cathode, and subsequently the ruthenium is separated from the sacrificial material. The purified ruthenium can then be utilized in numerous applications including, but not limited to, semiconductor device fabrication applications.

An exemplary method for purifying ruthenium through electrolytically processing is described with reference to the flow chart 80 of FIG. 4. An initial processing stage 82 comprises provision of a cathode which has a sacrificial material thereover. The cathode can, for example, comprise, consist essentially of, or consist of titanium. The sacrificial material formed over the cathode can, in particular aspects, comprise, consist essentially of, or consist of copper. The copper can be a thin layer formed over and in direct contact with (i.e. touching) the titanium of the cathode. Preferably, the copper layer entirely covers the cathode so that there are not exposed titanium-containing surfaces of the cathode during the electrolytic purification of ruthenium.

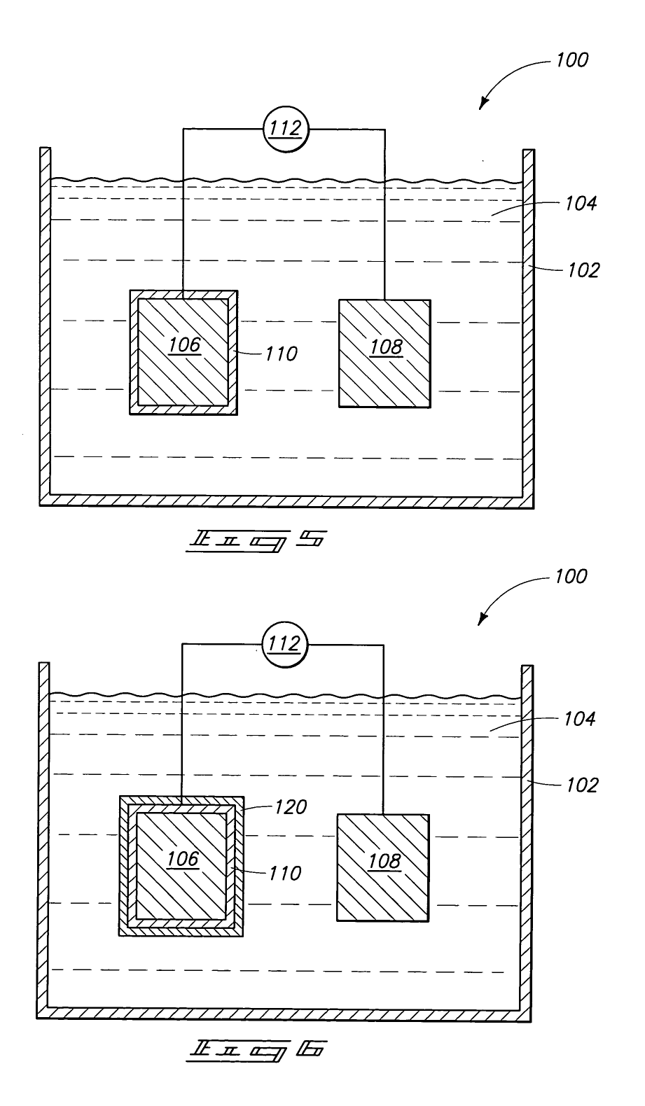

FIG. 5 illustrates an electrolytic apparatus 100 at the processing stage of step 82. Apparatus 100 comprises a vessel 102 having an electrolytic bath 104 retained therein. A cathode 106 is within the electrolytic bath, as is an anode 108. The cathode and anode are typically supported by appropriate supporting structures (not shown). The cathode has a thin layer 110 of sacrificial material thereover. The cathode is connected to the anode through a power source 112. Impure ruthenium can be provided either within bath 104, or as part of anode 108 at the processing stage of FIG. 5.

Referring again to FIG. 4, the processing stage 82 is followed by a processing stage 84 in which a ruthenium-containing material is electroplated onto the sacrificial material.

FIG. 6 shows the construction 100 at the processing stage 84 of FIG. 4, and shows a ruthenium-containing material 120 electroplated onto sacrificial material 110.

Referring again to FIG. 4, the processing stage 84 is followed by a processing stage 86 in which the ruthenium-containing material and sacrificial material are removed from the cathode. The ruthenium-containing material is then separated from the sacrificial material (processing stage 88 of FIG. 4).

The separation of the ruthenium-containing material from the sacrificial material can be accomplished by any suitable method. In aspects in which the sacrificial material comprises copper, such material can be separated from the ruthenium-containing material by dissolving the copper in an appropriate solvent which is substantially selective for copper relative to ruthenium. Appropriate solvents will be recognized by persons of ordinary skill in the art, and can include, for example, various acidic solutions.

The separated ruthenium can be utilized in any application in which high purity ruthenium is desired, including, for example, as a ruthenium-containing anode during electroplating of ruthenium, for forming high purity ruthenium powder, and/or as a starting material for forming high purity atomic layer deposition (ALD) or chemical vapor deposition (CVD) precursor.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

1. A method of forming a target/backing plate assembly, comprising:
providing a backing plate construction; and
electrolytically depositing a ruthenium-containing target onto the backing plate construction.

2. The method of claim 1 wherein the target comprises at least 99.9 weight percent ruthenium.

3. The method of claim 1 wherein the target comprises at least 99.99 weight percent ruthenium.

4. The method of claim 1 wherein the target comprises at least 99.995 weight percent ruthenium.

5. The method of claim 1 wherein the target comprises at least 99.999 weight percent ruthenium.

6. The method of claim 1 wherein:
the backing plate construction is in a container shape, the container shape having a closed end and an open end, the container shape having a sidewall extending from the closed end to the open end, the container shape comprising an interior region which includes an interior surface of the closed end and an interior surface of the sidewall; and
the ruthenium-containing target is electrolytically deposited along at least a portion of the interior region of the container shape.

7. The method of claim 6 wherein the ruthenium-containing target is electrolytically deposited to about a common uniform thickness across both the interior surface of the sidewall and the interior surface of the closed end.

8. The method of claim 6 wherein the ruthenium-containing target is electrolytically deposited so that a thickness of the target across the interior surface of the sidewall is thicker than any thickness of the ruthenium-containing target across a predominant portion of the interior surface of the closed end.

9. The method of claim 8 wherein there is substantially no thickness of the ruthenium-containing target across a predominant portion of the interior surface of the closed end.

10. The method of claim 9 wherein the ruthenium-containing target is electrically deposited while an anode is provided within the container shape of the interior of the backing plate construction, and wherein the anode is closer to the interior surface of the sidewall than to the interior surface of the closed end.

11. The method of claim 8 wherein there is no thickness of the ruthenium-containing target across the interior surface of the closed end.

12. The method of claim 11 wherein the ruthenium-containing target is electrically deposited while an anode is provided within the container shape of the interior of the backing plate construction, and wherein the anode is closer to the interior surface of the sidewall than to the interior surface of the closed end.

13. The method of claim 1 wherein the backing plate construction consists essentially of an aluminum-containing material.

14. The method of claim 1 wherein the backing plate construction consists essentially of a copper-containing material.

15. The method of claim 14 wherein the copper-containing material comprises at least 99.9 weight percent copper.

16. A method of electrolytically processing ruthenium, comprising:
providing a cathode;
providing an electrically conductive sacrificial material over the cathode;
electrolytically depositing a ruthenium-containing material on the sacrificial material;
removing the sacrificial material and ruthenium-containing material from the cathode; and
separating the ruthenium-containing material from the sacrificial material.

17. The method of claim 16 wherein the cathode consists essentially of titanium and wherein the sacrificial material consists essentially of copper.

18. The method of claim 16 wherein the ruthenium-containing material comprises at least 99.9 weight percent ruthenium after the ruthenium-containing material is separated from the sacrificial material.

19. The method of claim 16 wherein the ruthenium-containing material comprises at least 99.99 weight percent ruthenium after the ruthenium-containing material is separated from the sacrificial material.

20. The method of claim 16 wherein the ruthenium-containing material comprises at least 99.995 weight percent ruthenium after the ruthenium-containing material is separated from the sacrificial material.

21. A container-shaped physical vapor deposition target, comprising:
a first conductive material in a container shape, the container shape comprising an interior region within the container of the container shape; the first conductive material comprising an interior surface along the interior region; and
a ruthenium-containing material along at least a portion of the interior surface of the first conductive material and being of a different chemical composition than the first conductive material.

22. The construction of claim 21 wherein the first conductive material consists essentially of an aluminum-containing material.

23. The construction of claim 21 wherein the first conductive material consists essentially of a copper-containing material.

24. The construction of claim 23 wherein the copper-containing material comprises at least 99.9 weight % copper.

25. The construction of claim 21 wherein the ruthenium-containing material comprises at least 99.9 weight percent ruthenium.

26. The construction of claim 21 wherein the ruthenium-containing material comprises at least 99.99 weight percent ruthenium.

27. The construction of claim 21 wherein the ruthenium-containing material comprises at least 99.995 weight percent ruthenium.

28. The construction of claim 21 wherein:
the container shape has a closed end, an open end, and a sidewall extending from the closed end to the open end;
the container shape interior region includes an interior surface of the closed end and an interior surface of the sidewall; and
the ruthenium-containing material has about a common uniform thickness across both the interior surface of the sidewall and the interior surface of the closed end.

29. The construction of claim 21 wherein:
the container shape has a closed end, an open end, and a sidewall extending from the closed end to the open end;
the container shape interior region includes an interior surface of the closed end and an interior surface of the sidewall; and
a thickness of the ruthenium-containing material across the interior surface of the sidewall is thicker than any thickness of the ruthenium-containing material across a predominant portion of the interior surface of the closed end.

30. The construction of claim 29 wherein there is substantially no thickness of the ruthenium-containing material across the predominant portion of the interior surface of the closed end.

31. The construction of claim 29 wherein there is none of the ruthenium-containing material along the interior surface of the closed end.
